(19) United States
(12) Patent Application Publication
(10) Pub. No.: US 2024/0373564 A1
(43) Pub. Date: Nov. 7, 2024

(54) ASSEMBLY SHEET AND METHOD FOR PRODUCING ASSEMBLY SHEET

(71) Applicant: NITTO DENKO CORPORATION, Osaka (JP)

(72) Inventor: Makoto TSUNEKAWA, Osaka (JP)

(73) Assignee: NITTO DENKO CORPORATION, Osaka (JP)

(21) Appl. No.: 18/557,015

(22) PCT Filed: Jan. 26, 2022
(86) PCT No.: PCT/JP2022/002941

§ 371 Date: Oct. 24, 2023

(30) Foreign Application Priority Data
Apr. 26, 2021 (JP) 2021-074405

(51) Int. Cl. H05K 5/00; H05K 1/11

(52) U.S. Cl. CPC H05K 5/0026; H05K 1/115

(57) ABSTRACT

An assembly sheet includes a wiring circuit board, a frame, and a reinforcement portion. The wiring circuit board has a support layer, a base insulating layer, and a conductive pattern. The frame supports the wiring circuit board. The frame has a through hole. The reinforcement portion is disposed on the edge of the through hole. The reinforcement portion reinforces the edge of the through hole.

### TECHNICAL FIELD

The present invention relates to an assembly sheet and a method for producing an assembly sheet.

### BACKGROUND ART

Conventionally, a wiring circuit board printed sheet having a plurality of wiring circuit boards has been known (ref: for example, Patent Document 1 below).

In production of the wiring circuit board printed sheet described above, after a wiring circuit element is formed on a metal support sheet, the metal support sheet around the wiring circuit element is etched, thereby forming an outer shape of the wiring circuit board.

Thereafter, when an etching resist used in the etching of the metal support sheet is peeled, the wiring circuit board printed sheet is immersed in a peeling solution, while being sandwiched by a mesh plate.

The wiring circuit board printed sheet has a through hole. A pin of the mesh plate is inserted into the through hole of the wiring circuit board printed sheet in a state where the wiring circuit board printed sheet is sandwiched by the mesh plate.

### CITATION LIST

### Patent Document

Patent Document 1: Japanese Unexamined Patent Publication No. 2006-210416

### SUMMARY OF THE INVENTION

### Problem to be Solved by the Invention

It is considered that the wiring circuit board printed sheet in a state of the wiring circuit board printed sheet having the plurality of wiring circuit boards (without individually separating the plurality of wiring circuit boards) is processed or conveyed by inserting a pin or the like into the through hole as described in Patent Document 1.

In this case, according to a processing method and a conveyance method, there is a possibility that the load is concentrated on the edge of the through hole, and the wiring circuit board printed sheet is broken with the through hole as a starting point.

The present invention provides an assembly sheet capable of suppressing a break of the assembly sheet with a through hole as a starting point, and a method for producing an assembly sheet.

### Means for Solving the Problem

The present invention [1] includes an assembly sheet including a wiring circuit board having a support layer, an insulating layer disposed on one surface of the support layer in a thickness direction, and a conductive pattern disposed on one surface of the insulating layer in the thickness direction; a frame supporting the wiring circuit board and having a through hole; and a reinforcement portion disposed on the edge of the through hole and reinforcing the edge of the through hole.

According to such a configuration, by reinforcing at least the edge of the through hole, it is possible to suppress a break of the frame with the through hole as a starting point.

The present invention [2] includes the assembly sheet of the above-described [1], wherein the frame is made of a metal foil having a thickness of 50 μm or less and a thickness of the reinforcement portion is 6 μm or more.

According to such a configuration, when the frame made of the thin metal foil is provided, it is possible to reinforce the edge of the through hole.

The present invention [3] includes the assembly sheet of the above-described [2], wherein when a thickness of the frame is 100%, the thickness of the reinforcement portion is 50% or more.

The present invention [4] includes the assembly sheet of any one of the above-described [1] to [3], wherein the reinforcement portion has a second through hole communicating with the through hole, and an inner surface of the second through hole is flush with the inner surface of the through hole.

According to such a configuration, it is possible to intensively reinforce the edge of the through hole.

The present invention [5] includes the assembly sheet of any one of the above-described [1] to [4], wherein the through hole is capable of receiving an instrument for suspending the assembly sheet.

According to such a configuration, it is possible to handle the assembly sheet in a state of being suspended by the instrument.

Therefore, it is possible to improve handleability of the assembly sheet.

The present invention [6] includes a method for producing an assembly sheet, the assembly sheet of any one of the above-described [1] to [5], including a patterning step of forming an insulating layer and a conductive pattern on one surface of a metal foil drawn from a first roll as a roll of the metal foil, forming a reinforcement portion on one surface of the metal foil, and forming a through hole in the metal foil to produce a second roll having the plurality of assembly sheets; and a cutting step of cutting each of the plurality of assembly sheets from the second roll, wherein the through bole receives an instrument for suspending the cut assembly sheet.

According to such a configuration, it is possible to handle the cut assembly sheet in a state of being suspended by the instrument.

Therefore, it is possible to improve the handleability of the cut assembly sheet.

The present invention [7] includes the method for producing an assembly sheet of the above-described [6] further including a plating step of plating a terminal of the conductive pattern, wherein the through hole receives the instrument in the plating step.

According to such a configuration, it is possible to improve the handleability of the cut assembly sheet in the plating step.

### Effect of the Invention

According to the assembly sheet and the method for producing an assembly sheet of the present invention, it is possible to suppress a break of the assembly sheet with a through hole as a starting point.

### BRIEF DESCRIPTION OF THE DRAWINGS

FIG. 1 shows a plan view of an assembly sheet as one embodiment of the present invention.

FIG. 2A shows an A-A cross-sectional view of the assembly sheet shown in FIG. 1.

FIG. 2B shows a B-B cross-sectional view of the assembly sheet shown in FIG. 1.

FIGS. 3A to 3C show explanatory views for illustrating a patterning step of a method for producing the assembly sheet shown in FIG. 1:

FIG. 3A illustrating a step of forming a base insulating layer on a metal foil,

FIG. 3B illustrating a step of forming a conductive layer on the base insulating layer, and forming a reinforcement portion on the metal foil, and

FIG. 3C illustrating a step of etching the metal foil to form a through hole in the metal foil and a cut-out between a frame and a wiring circuit board.

FIG. 4A, subsequent to FIG. 3C, shows an explanatory view for illustrating a cutting step of the method for producing an assembly sheet.

FIG. 4B, subsequent to FIG. 4A, shows an explanatory view for illustrating a plating step of the method for producing an assembly sheet.

FIG. 5 shows an explanatory view for illustrating a first modified example.

FIG. 6 shows an explanatory view for illustrating a second modified example.

FIGS. 7A and 7B show explanatory views for illustrating a third modified example:

FIG. 7A illustrating a step of forming a conductive layer on a base insulating layer, and forming a reinforcement portion without a through hole on a metal foil and

FIG. 7B illustrating a step of etching the metal foil and the reinforcement portion to form the through hole in the metal foil, the through hole in the reinforcement portion, and a cut-out between a frame and a wiring circuit board.

FIGS. 8A to 8C show explanatory views for illustrating a fourth modified example:

FIG. 8A illustrating a step of forming a conductive layer on a base insulating layer, and forming a reinforcement portion without a through hole on a metal foil,

FIG. 8B illustrating a step of etching the metal foil to form a cut-out between a frame and a wiring circuit board, and

FIG. 8C illustrating a step of punching the metal foil and the reinforcement portion to form the through hole in the metal foil and the through hole in the reinforcement portion.

FIGS. 9A to 9D show explanatory views for illustrating a fifth modified example:

FIG. 9A illustrating a step of forming a base insulating layer on a metal foil,

FIG. 9B illustrating a step of forming a conductive layer on the base insulating layer,

FIG. 9C illustrating a step of etching the metal foil to form a through hole in the metal foil and a cut-out between a frame and a wiring circuit board, and

FIG. 9D illustrating a step of forming a reinforcement portion on the edge of the through hole and at the inside of the through hole.

FIG. 10 shows an explanatory view for illustrating a sixth modified example, and shows a case where the reinforcement portion is formed on both surfaces of the metal foil in the fifth modified example.

FIG. 11 shows an explanatory view for illustrating a seventh modified example.

FIG. 12 shows an explanatory view for illustrating an eighth modified example.

FIG. 13 shows an explanatory view for illustrating a ninth modified example.

FIGS. 14A and 14B show explanatory views for illustrating a tenth modified example:

FIG. 14A illustrating a cross-sectional view corresponding to an A-A line of FIG. 1 and

FIG. 14B illustrating a cross-sectional view corresponding to a B-B line of FIG. 1.

FIGS. 15A and 15B show explanatory views for illustrating an eleventh modified example:

FIG. 15A illustrating a cross-sectional view corresponding to an A-A line of FIG. 1 and

FIG. 15B illustrating a cross-sectional view corresponding to a B-B line of FIG. 1.

FIG. 16 shows an explanatory view for illustrating a twelfth modified example.

### DESCRIPTION OF EMBODIMENTS

### 1. Assembly Sheet

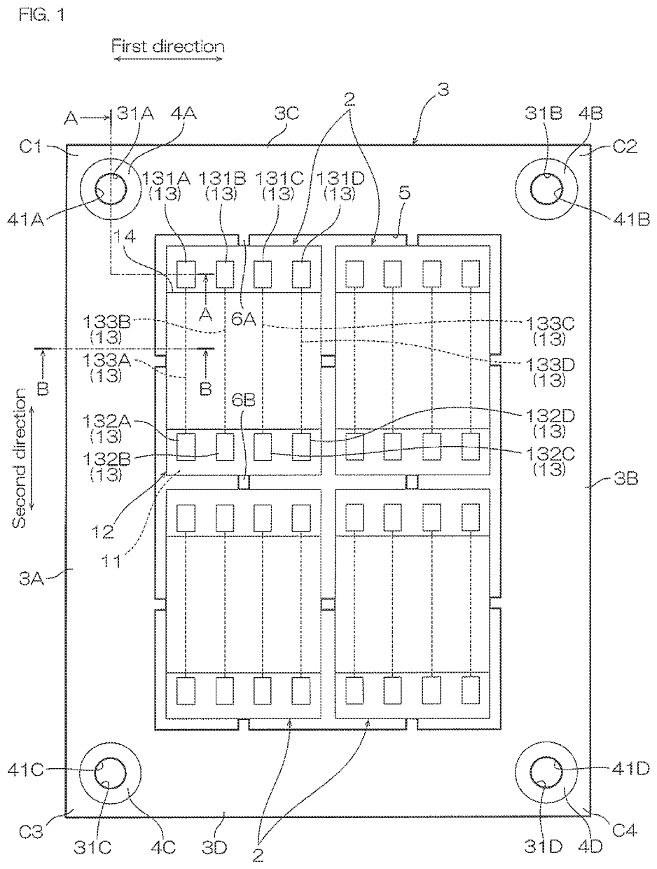

As shown in FIG. 1, an assembly sheet 1 has a sheet shape extending in a first direction and a second direction. The second direction is perpendicular to the first direction. The assembly sheet 1 includes a plurality of wiring circuit boards 2, a frame 3, and a plurality of reinforcement portions 4A, 4B, 4C, and 4D.

### (1) Wiring Circuit Board

The plurality of wiring circuit boards 2 are disposed spaced from each other in the second direction, while disposed spaced from each other in the first direction. Each of the plurality of wiring circuit boards 2 has the same structure. Therefore, one of the wiring circuit boards 2 of the plurality of wiring circuit boards 2 is described, and descriptions of the other wiring circuit boards 2 are omitted.

The wiring circuit board 2 extends in the first direction and the second direction. In this embodiment, the wiring circuit board 2 has a generally rectangular shape. A shape of the wiring circuit board 2 is not limited.

The wiring circuit board 2 has a support layer 11, a base insulating layer 12 as one example of an insulating layer, a conductive pattern 13, and a cover insulating layer 14.

### (1-1) Support Layer

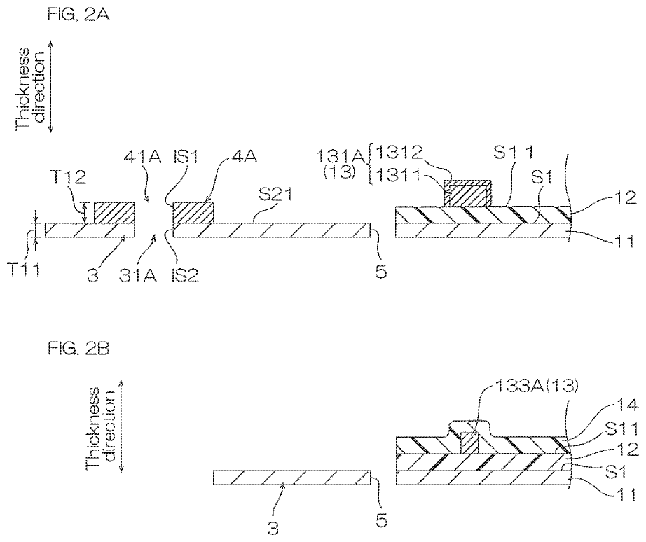

As shown in FIG. 2A, the support layer 11 supports the base insulating layer 12, the conductive pattern 13, and the cover insulating layer 14 (ref: FIG. 2B). In this embodiment, the support layer 11 is made of a metal foil. Examples of a metal include stainless steel and copper alloys.

A thickness of the metal foil, that is, the thickness of the support layer 11 is, for example, 50 μm or less, preferably 30 μm or less, and for example, 10 μm or more, preferably 15 μm or more.

### (1-2) Base Insulating Layer

The base insulating layer 12 is disposed on a one-surface S1 of the support layer 11 in a thickness direction. The thickness direction is perpendicular to the first direction and the second direction. The base insulating layer 12 is disposed between the support layer 11 and the conductive pattern 13 in the thickness direction. The base insulating layer 12 insulates the support layer 11 from the conductive pattern 13. The base insulating layer 12 is made of a resin. An example of the resin includes polyimide.

The thickness of the base insulating layer 12 is, for example, 30 μm or less, preferably 15 μm or less, and for example, 1 μm or more, preferably 3 μm or more.

### (1-3) Conductive Pattern

The conductive pattern 13 is disposed on a one-surface S11 of the base insulating layer 12 in the thickness direction. The conductive pattern 13 is disposed on the opposite side to the support layer 11 with respect to the base insulating layer 12 in the thickness direction. A shape of the conductive pattern 13 is not limited.

In this embodiment, as shown in FIG. 1, the conductive pattern 13 has a plurality of terminals 131A, 131B, 131C, and 131D; a plurality of terminals 132A, 132B, 132C, and 132D; and a plurality of wirings 133A, 133B, 133C, and 133D. The number of terminals and the number of wirings are not limited.

### (1-3-1) Terminal

The terminals 131A, 131B, 131C, and 131D are disposed in one end portion of the wiring circuit board 2 in the second direction. In this embodiment, the terminals 131A, 131B, 131C, and 131D are disposed spaced from each other in the first direction. Each of the terminals 131A, 131B, 131C, and 131D has a square land shape.

As shown in FIG. 2A, the terminal 131A has a conductive layer 1311 and a plating layer 1312.

The conductive layer 1311 is a main body portion of the terminal 131A. The conductive layer 1311 is disposed on the one-surface S11 of the base insulating layer 12 in the thickness direction. The conductive layer 1311 is made of the metal. An example of the metal includes copper.

The thickness of the conductive layer 1311 is, for example, 3 μm or more, preferably 5 μm or more, and for example, 50 μm or less, preferably 30 μm or less.

The plating layer 1312 covers the surface of the conductive layer 1311. The plating layer 1312 suppresses corrosion of the conductive layer 1311. The plating layer 1312 is made of the metal. Examples of the metal include nickel, gold, and tin. The plating layer 1312 may consist of one layer or may consist of a plurality of layers. When the plating layer 1312 consists of the plurality of layers, each of the plurality of layers may be made of metals different from each other.

The thickness of the plating layer 1312 is, for example, 0.1 μm or more, preferably 0.2 μm or more, and for example, 5 μm or less. preferably 4 μm or less.

The terminals 131B, 131C, and 131D have the same structure as the terminal 131A. Therefore, the descriptions of the terminals 131B, 131C, and 131D are omitted.

As shown in FIG. 1, the terminals 132A, 132B, 132C, and 132D are disposed in the other end portion of the wiring circuit board 2 in the second direction. In this embodiment, the terminals 132A, 132B, 132C, and 132D are disposed spaced from each other in the first direction. Each of the terminals 132A, 132B, 132C, and 132D has a square land shape.

The terminals 132A, 132B, 132C, and 132D have the same structure as the terminal 131A. Therefore, the descriptions of the terminals 132A, 132B, 132C, and 132D are omitted.

### (1-3-2) Wiring

One end of the wiring 133A is connected to the terminal 131A. The other end of the wiring 133A is connected to the terminal 132A. The wiring 133A electrically connects the terminal 131A to the terminal 132A.

One end of the wiring 133B is connected to the terminal 131B. The other end of the wiring 133B is connected to the terminal 132B. The wiring 133B electrically connects the terminal 131B to the terminal 132B.

One end of the wiring 133C is connected to the terminal 131C. The other end of the wiring 133C is connected to the terminal 132C. The wiring 133C electrically connects the terminal 131C to the terminal 132C.

One end of the wiring 133D is connected to the terminal 131D. The other end of the wiring 133D is connected to the terminal 132D. The wiring 133D electrically connects the terminal 131D to the terminal 132D.

In the following descriptions, each of the terminals 131A, 131B, 131C, and 131D is referred to as a terminal 131; each of the terminals 132A, 132B, 132C, and 132D is referred to as a terminal 132; and each of the wirings 133A. 133B, 133C, and 133D is referred to as a wiring 133.

As shown in FIG. 2B, the wiring 133 is made of the same metal as the conductive layer 1311 (ref: FIG. 2A) of the terminal 131. The thickness of the wiring 133 is, for example, 3 μm or more, preferably 5 μm or more, and for example, 50 μm or less, preferably 30 μm or less.

### (1-4) Cover Insulating Layer

As shown in FIG. 1, the cover insulating layer 14 covers all of the wirings 133. The cover insulating layer 14 is disposed on the base insulating layer 12 in the thickness direction. The cover insulating layer 14 does not cover the terminals 131 and the terminals 132. The cover insulating layer 14 is made of the resin. An example of the resin includes polyimide.

The thickness of the cover insulating layer 14 is, for example, 30 μm or less, preferably 15 μm or less, and for example, 1 μm or more, preferably 3 μm or more.

### (2) Frame

The frame 3 is disposed on the outer periphery of the assembly sheet 1. The frame 3 surrounds the plurality of wiring circuit boards 2. In this embodiment, the frame 3 has a frame shape. Specifically, the frame 3 has a first frame 3A, a second frame 3B, a third frame 3C, and a fourth frame 3D.

The first frame 3A is disposed in one end portion of the assembly sheet 1 in the first direction. The first frame 3A extends in the second direction.

The second frame 3B is disposed in the other end portion of the assembly sheet 1 in the first direction. The second frame 3B is disposed away from the first frame 3A in the first direction. The plurality of wiring circuit boards 2 are disposed between the first frame 3A and the second frame 3B in the first direction. The second frame 3B extends in the second direction.

The third frame 3C is disposed in one end portion of the assembly sheet 1 in the second direction. The third frame 3C extends in the first direction. One end portion of the third frame 3C in the first direction is connected to one end portion of the first frame 3A in the second direction at a corner C1 of the assembly sheet 1. The other end portion of the third frame 3C in the first direction is connected to one end portion of the second frame 3B in the second direction at a corner C2 of the assembly sheet 1.

The fourth frame 3D is disposed in the other end portion of the assembly sheet 1 in the second direction. The fourth frame 3D is disposed away from the third frame 3C in the second direction. The plurality of wiring circuit boards 2 are disposed between the third frame 3C and the fourth frame 3D in the second direction. The fourth frame 3D extends in the first direction. One end portion of the fourth frame 3D in the first direction is connected to the other end portion of the first frame 3A in the second direction at a corner C3 of the assembly sheet 1. The other end portion of the fourth frame 3D in the first direction is connected to the other end portion of the second frame 3B in the second direction at a corner C4 of the assembly sheet 1.

As shown in FIG. 2A, the frame 3 is made of the metal foil. The frame 3 is made of the same metal foil as the support layer 11 of the wiring circuit board 2. Examples of the metal include stainless steel and copper alloys. The thickness of the metal foil, that is, a thickness T11 of the frame 3 is, for example, 50 μm or less, preferably 30 μm or less, and for example, 10 μm or more, preferably 15 μm or more.

When the thickness T11 of the frame 3 is the above-described upper limit value or less, rigidity of the frame 3 is low. Therefore, when the assembly sheet 1 is handled, there is a possibility that wrinkles occur in the assembly sheet 1. Therefore, handling of the assembly sheet 1 is difficult.

Examples of a case of the difficult handling of the assembly sheet 1 include a case of carrying the assembly sheet 1, and a plating step in the method for producing the assembly sheet 1 to be described later.

Further, in this embodiment, the assembly sheet 1 has a cut-out 5 between the frame 3 and the wiring circuit board 2, and the two wiring circuit boards 2. Therefore, the rigidity of the entire assembly sheet 1 is further low. Therefore, the handling of the assembly sheet 1 is more difficult.

The assembly sheet 1 has a connecting portion 6A (ref: FIG. 1) which connects the frame 3 to the wiring circuit board 2, and a connecting portion 6B (ref: FIG. 1) which connects the two wiring circuit boards 2 to each other. The plurality of wiring circuit boards 2 are supported by the frame 3 via the connecting portion 6A. while being connected to each other via the connecting portion 6B.

As shown in FIG. 1, the frame 3 has a plurality of through holes 31A, 31B, 31C, and 31D.

In this embodiment, the through hole 31A is located at the corner C1. The through hole 31B is located at the corner C2. The through hole 31C is located at the corner C3. The through hole 31D is located at the corner C4. In this embodiment, each of the through holes 31A, 31B, 31C, and 31D has a circular shape. Each of the through holes 31A, 31B, 31C, and 31D is capable of receiving an instrument for suspending the assembly sheet 1.

The instrument for suspending the assembly sheet 1 is not limited. Examples of the instrument for suspending the assembly sheet 1 include bars, wires, pins, and hooks.

In the following descriptions, each of the through holes 31A, 31B, 31C, and 31D is referred to as a through hole 31. The number, the arrangement, and the shape of the through holes 31 are not limited.

### (3) Reinforcement Portion

As shown in FIG. 1, in this embodiment, the reinforcement portion 4A is disposed on the edge of the through hole 31A. The reinforcement portion 4A extends along the edge of the through hole 31A. The reinforcement portion 4A surrounds the through hole 31A. In other words. the reinforcement portion 4A has a through hole 41A. The through hole 41A communicates with the through hole 31A.

The reinforcement portion 4B is disposed on the edge of the through hole 31B. The reinforcement portion 4B extends along the edge of the through hole 31B. The reinforcement portion 4B surrounds the through hole 31B. In other words, the reinforcement portion 4B has a through hole 41B. The through hole 41B communicates with the through hole 31B.

The reinforcement portion 4C is disposed on the edge of the through hole 31C. The reinforcement portion 4C extends along the edge of the through hole 31C. The reinforcement portion 4C surrounds the through hole 31C. In other words, the reinforcement portion 4C has a through hole 41C. The through hole 41C communicates with the through hole 31C.

The reinforcement portion 4D is disposed on the edge of the through hole 31D. The reinforcement portion 4D extends along the edge of the through hole 31D. The reinforcement portion 4D surrounds the through hole 31D. In other words, the reinforcement portion 4D has a through hole 41D. The through hole 41D communicates with the through hole 31D.

In the following descriptions, each of the reinforcement portions 4A. 4B, 4C, and 4D is referred to as a reinforcement portion 4. Each of the through holes 41A, 41B, 41C, and 41D is referred to as a through hole 41.

In this embodiment, the reinforcement portion 4 has a circular shape. The shape of the reinforcement portion 4 is not limited. In this embodiment, the reinforcement portion 4 may also have a quadrangular shape. The reinforcement portion 4 may be intermitted.

As shown in FIG. 2A, in this embodiment, the reinforcement portion 4 is disposed on a one-surface S21 of the frame 3 in the thickness direction. The reinforcement portion 4 is made of the metal. The reinforcement portion 4 is preferably made of the same metal as the conductive layer 1311 of the terminal 131. When the reinforcement portion 4 and the conductive layer 1311 are the same metal, it is possible to form the reinforcement portion 4 by using a step of forming the conductive layer 1311.

A thickness T12 of the reinforcement portion 4 is, for example, 6 μm or more, preferably 10 μm or more. and for example, 100 μm or less, preferably 60 μm or less.

When the thickness T11 of the frame 3 is 100%, the thickness T12 of the reinforcement portion 4 is, for example, 50% or more, preferably 80% or more, more preferably 100% or more, and for example, 300% or less, preferably 250% or less.

When the thickness T12 of the reinforcement portion 4 in a case where the thickness T11 of the frame 3 is 100% is the above-described lower limit value or more, it is possible to further improve the strength of the edge of the through hole 31.

An inner surface IS1 of the through hole 41 may be away from an inner surface IS2 of the through hole 31. An interval between the inner surface IS1 of the through hole 41 and the inner surface IS2 of the through hole 31 is, for example, below 5 μm, preferably 3 μm or less, more preferably 1 μm or less, further more preferably 0 μm. In other words. the inner surface ISI of the through hole 41 is preferably flush with the inner surface IS2 of the through hole 31.

### 2. Method for Producing Assembly Sheet

Next, a method for producing the above-described assembly sheet 1 is described.

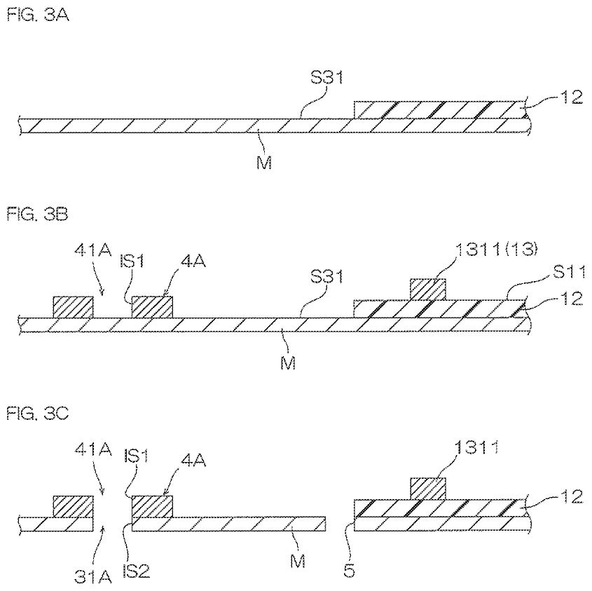

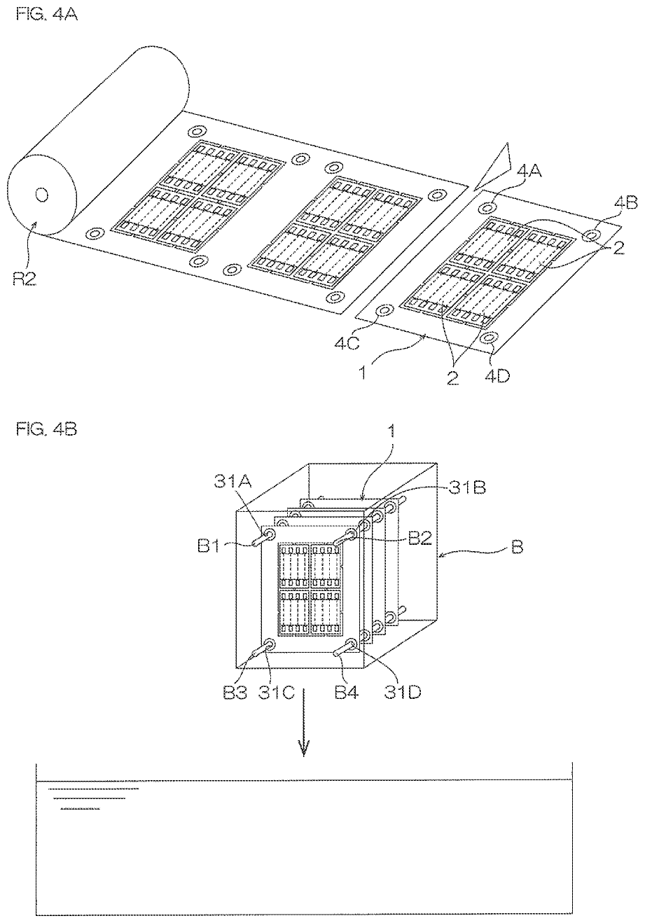

In this embodiment, the assembly sheet 1 is produced by a semi-additive method. The assembly sheet 1 may be also produced by an additive method. The method for producing the assembly sheet 1 includes a patterning step (ref: FIGS. 3A to 3C), a cutting step (ref: FIG. 4A), and a plating step (ref: FIG. 4B).

### (1) Patterning Step

As shown in FIGS. 3A to 3C, in the patterning step, the base insulating layer 12 (ref: FIG. 3A) and the conductive pattern 13 (ref: FIG. 3B) are formed on a one-surface S31 of a metal foil M drawn from a first roll R1 (not shown) which is a roll of the metal foil: the reinforcement portion 4 (ref: FIG. 3B) is formed on the one-surface S31 of the metal foil M; and the through hole 31 (ref: FIG. 3C) is formed in the metal foil M, to produce a second roll R2 (ref: FIG. 4A) having the plurality of assembly sheets 1. The metal foil M is stretched between the first roll R1 and the second roll R2 during the pattering step.

Specifically, in order to form the base insulating layer 12, first, a solution (varnish) of a photosensitive resin is coated on the one-surface S31 of the metal foil M and dried to form a coating film of the photosensitive resin. Next, the coating film of the photosensitive resin is exposed to light and developed.

Thus, as shown in FIG. 3A, the base insulating layer 12 is formed on the one-surface S31 of the metal foil M.

The conductive pattern 13 and the reinforcement portion 4 are formed by electrolytic plating.

In order to form the conductive pattern 13 and the reinforcement portion 4 by the electrolytic plating, first, a seed layer is formed on the one-surface S11 of the base insulating layer 12 and the one-surface S31 of the metal foil M. The seed layer is, for example, formed by sputtering. Examples of a material for the seed layer include chromium, copper, nickel, titanium, and alloys of these.

Next, a plating resist is attached onto the one-surface S11 of the base insulating layer 12 and the one-surface S31 of the metal foil M.

Next, the plating resist is exposed to light, while portions where the conductive layer 1311 (ref: FIG. 2A), the wiring 133 (ref: FIG. 2B), and the reinforcement portion 4 (ref: FIG. 2A) are formed are shielded.

Next, the exposed plating resist is developed. Then, the plating resist of the shielded portion is removed, and the seed layer is exposed to the portions where the conductive layer 1311, the wiring 133, and the reinforcement portion 4 are formed. The plating resist of the exposed portion, that is, the portions where the conductive layer 1311, the wiring 133, and the reinforcement portion 4 are not formed remains.

Next, the conductive layer 1311, the wiring 133, and the reinforcement portion 4 are formed on the exposed seed layer by the electrolytic plating. After the electrolytic plating is completed, the plating resist is peeled. Thereafter, the seed layer exposed by peeling the plating resist is removed by etching.

Thus, as shown in FIG. 3B, the conductive layer 1311 and the wiring 133 are formed on the one-surface S11 of the base insulating layer 12, and the reinforcement portion 4 is formed on the one-surface S31 of the metal foil M.

Next, the cover insulating layer 14 (ref: FIGS. 1 and 2B) is formed on the base insulating layer 12 and the conductive pattern 13 in the same manner as the formation of the base insulating layer 12.

Next, as shown in FIG. 3C, the metal foil M is etched to form the through hole 31. Further, the cut-out 5 is formed between the frame 3 and the wiring circuit board 2, and between the two wiring circuit boards 2.

As described above, the second roll R2 having the plurality of assembly sheets 1 is produced.

### (2) Cutting Step

Next, after the patterning step, the cutting step is carried out.

As shown in FIG. 4A, in the cutting step, each of the plurality of assembly sheets 1 is cut from the second roll R2. Specifically, the assembly sheet 1 which is fed out from the second roll R2 is cut out with a cutter. A method for cutting is not limited. Thus, the plurality of assembly sheets 1 which are independent of each other are obtained.

### (3) Plating Step

Next, after the cutting step, the plating step is carried out.

In the plating step, the conductive layers 1311 of all of the terminals 131 and the conductive layers 1311 of all of the terminals 132 of the cut assembly sheet 1 are plated. In the plating step, the conductive layer 1311 is plated by electroless plating. Thus, the plating layer 1312 (ref: FIG. 2A) is formed on the surface of the conductive layer 1311.

Specifically, as shown in FIG. 4B, the plurality of cut assembly sheets 1 are collectively placed in a basket B, and is immersed together with the basket B in a plating solution.

At this time, the assembly sheet 1 is suspended at the inside of the basket B. In this embodiment, the assembly sheet 1 is suspended in the basket B in a state where a bar B1 is inserted into the through hole 31A. a bar B2 is inserted into the through hole 31B, a bar B3 is inserted into the through hole 31C, and a bar B4 is inserted into the through hole 31D. In other words, the through hole 31 receives the bars as an instrument for suspending the cut assembly sheet 1 in the plating step. Thus, it is possible to improve handleability of the cut assembly sheet 1. Further, the assembly sheet 1 is suspended in the basket B in a state where transfer of the four corners C1, C2, C3, and C4 are restricted. Therefore, it is possible to suppress the occurrence of the wrinkles in the assembly sheet 1 during the plating step.

Further, by reinforcing the edge of the through hole 31 by the reinforcement portion 4, it is possible to suppress a break of the frame 3 with the through hole 31 as a starting point, and to stably suspend the assembly sheet 1 in the basket B.

### 3. Function and Effect

(1) According to the assembly sheet 1, as shown in FIGS. 1 and 2A, by reinforcing the edge of the through hole 31, it is possible to suppress the break of the frame 3 with the through hole 31 as the starting point.

(2) According to the assembly sheet 1, the frame 3 is made of the metal foil having a thickness of 50 μm or less and the thickness of the reinforcement portion 4 is 6 μm or more.

Therefore, when the frame 3 made of the thin metal foil is provided, it is possible to reinforce the edge of the through hole 31.

(3) According to the assembly sheet 1, as shown in FIG. 2A, the inner surface IS1 of the through hole 41 of the reinforcement portion 4 is flush with the inner surface IS2 of the through hole 31.

Therefore, it is possible to intensively reinforce the edge of the through hole 41.

(4) According to the assembly sheet 1, as shown in FIG. 4B, it is possible to suspend the assembly sheet 1, for example, in the basket B. In a state where the assembly sheet 1 is suspended in the basket B, the through hole 4A receives the bar B1 for suspending the assembly sheet 1. the through hole 4B receives the bar B2 for suspending the assembly sheet 1, the through hole 4C receives the bar B3 for suspending the assembly sheet 1, and the through hole 4D receives the bar B4 for suspending the assembly sheet 1.

Thus, it is possible to handle the assembly sheet 1 in a state of being suspended by the bars B1, B2, B3, and B4.

As a result, it is possible to improve the handleability of the assembly sheet 1.

(5) According to the method for producing the assembly sheet 1, as shown in FIGS. 3B and 3C. it is possible to form the reinforcement portion 4 and the thorough hole 31, while the metal foil M is stretched between the first roll R1 and the second roll R2.

Then, as shown in FIG. 4B, it is possible to handle the cut assembly sheet 1 in a state of being suspended by the bars B1, B2, B3, and B4.

As a result, it is possible to improve the handleability of the cut assembly sheet 1.

(6) According to the method for producing the assembly sheet 1, as shown in FIG. 4B, the terminal 131 and the terminal 132 of the cut assembly sheet 1 are plated in the plating step.

In the plating step, it is possible to immerse the cut assembly sheet 1 in the plating solution in a state of being suspended by the bars B1, B2, B3, and B4.

Therefore, it is possible to improve the handleability of the cut assembly sheet 1 in the plating step.

### 4. Modified Examples

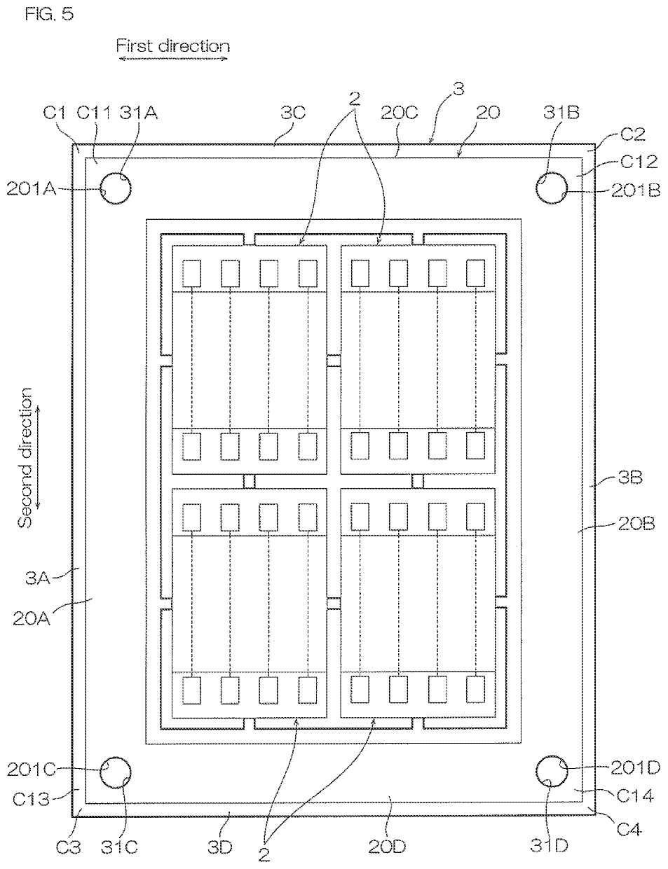

Next, modified examples are described with reference to FIGS. 5 to 16. In each modified example, the same reference numerals are provided for members corresponding to each of those in the above-described embodiment, and their detailed description is omitted.

(1) The shape of the reinforcement portion 4 is not limited as long as the reinforcement portion 4 is disposed at least on the edge of the through hole 31, and a configuration used for production of the wiring circuit board 2 is avoided.

For example, as shown in FIG. 5, a reinforcement portion 20 may also have a frame shape.

Specifically, the reinforcement portion 20 has a first reinforcement portion 20A, a second reinforcement portion 20B, a third reinforcement portion 20C, and a fourth reinforcement portion 20D.

The first reinforcement portion 20A is disposed on the first frame 3A. The first reinforcement portion 20A reinforces the first frame 3A. The first reinforcement portion 20A extends in the second direction. In other words, the first reinforcement portion 20A extends in a direction in which the first frame 3A extends.

The second reinforcement portion 20B is disposed on the second frame 3B. The second reinforcement portion 20B reinforces the second frame 3B. The second reinforcement portion 20B extends in the second direction. In other words, the second reinforcement portion 20B extends in a direction in which the second frame 3B extends.

The third reinforcement portion 20C is disposed on the third frame 3C. The third reinforcement portion 20C reinforces the third frame 3C. The third reinforcement portion 20C extends in the first direction. In other words, the third reinforcement portion 20C extends in a direction in which the third frame 3C extends. One end portion of the third reinforcement portion 20C in the first direction is connected to one end portion of the first reinforcement portion 20A in the second direction at a corner C11 of the reinforcement portion 20. The other end portion of the third reinforcement portion 20C in the first direction is connected to one end portion of the second reinforcement portion 20B in the second direction at a corner C12 of the reinforcement portion 20.

The fourth reinforcement portion 20D is disposed on the fourth frame 3D. The fourth reinforcement portion 20D reinforces the fourth frame 3D. The fourth reinforcement portion 20D extends in the first direction. In other words, the fourth reinforcement portion 20D extends in a direction in which the fourth frame 3D extends. One end portion of the fourth reinforcement portion 20D in the first direction is connected to the other end portion of the first reinforcement portion 20A in the second direction at a corner C13 of the reinforcement portion 20. The other end portion of the fourth reinforcement portion 20D in the first direction is connected to the other end portion of the second reinforcement portion 20B in the second direction at a corner C14 of the reinforcement portion 20.

The corner C11 of the reinforcement portion 20 is disposed on the edge of the through hole 31A. The corner C12 of the reinforcement portion 20 is disposed on the edge of the through hole 31B. The corner C13 of the reinforcement portion 20 is disposed on the edge of the through hole 31C. The corner C14 of the reinforcement portion 20 is disposed on the edge of the through hole 31D.

The reinforcement portion 20 has through holes 201A, 201B, 201C, and 201D. The through hole 201A is disposed at the corner C11 of the reinforcement portion 20. The through hole 201A communicates with the through hole 31A. The through hole 201B is disposed at the corner C12 of the reinforcement portion 20. The through hole 201B communicates with the through hole 31B. The through hole 201C is disposed at the corner C13 of the reinforcement portion 20. The through hole 201C communicates with the through hole 31C. The through hole 201D is disposed at the corner C14 of the reinforcement portion 20. The through hole 201D communicates with the through hole 31D.

(2) As shown in FIG. 6, the frame 3 may be also between the two wiring circuit boards 2. In this case. the reinforcement portion 20 may be also provided on the frame 3 between the two wiring circuit boards 2.

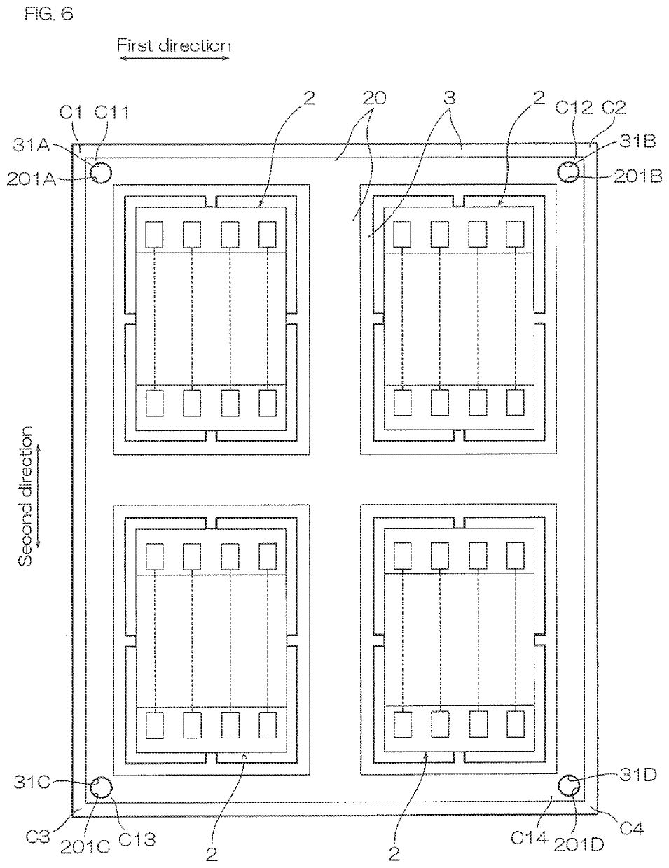

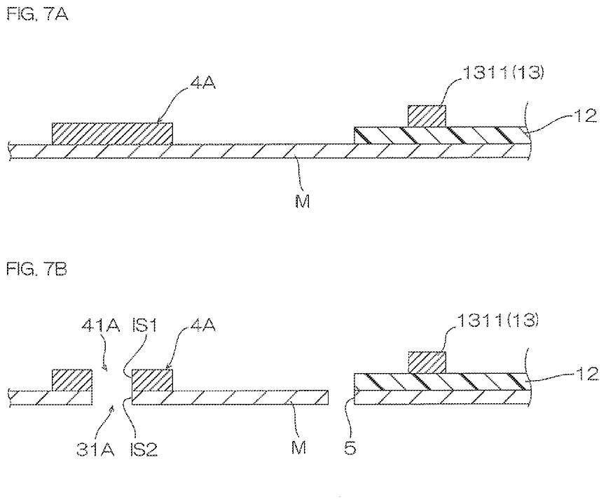

(3) As shown in FIG. 7A, in the patterning step, the reinforcement portion 4 without the through hole 41 is formed on the metal foil M, and as shown in FIG. 7B, when the metal foil M is etched, the reinforcement portion 4 may be also etched to form the through hole 31 and the through hole 41.

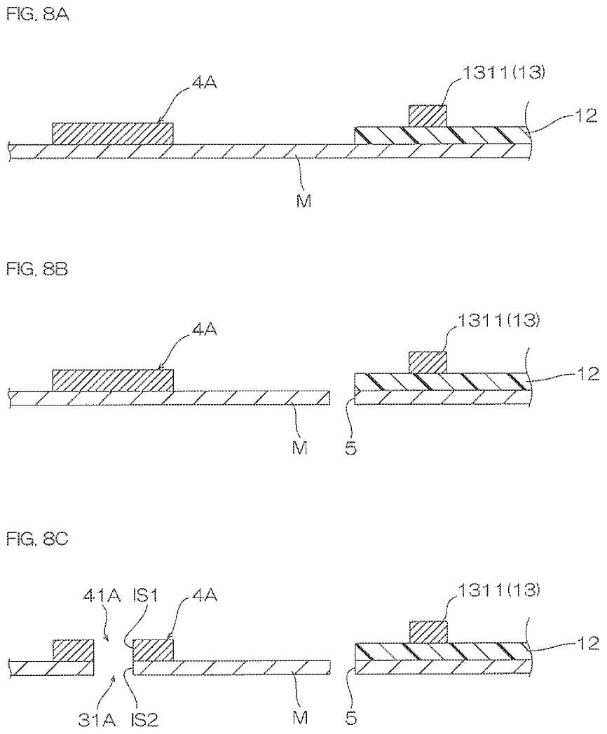

(4) As shown in FIG. 8A, in the patterning step, the reinforcement portion 4 without the through hole 41 is formed on the metal foil M; as shown in FIG. 8B, the metal foil M is etched: and thereafter, as shown in FIG. 8C, the reinforcement portion 4 and the metal foil M may be also punched. to form the through hole 31 and the through hole 41.

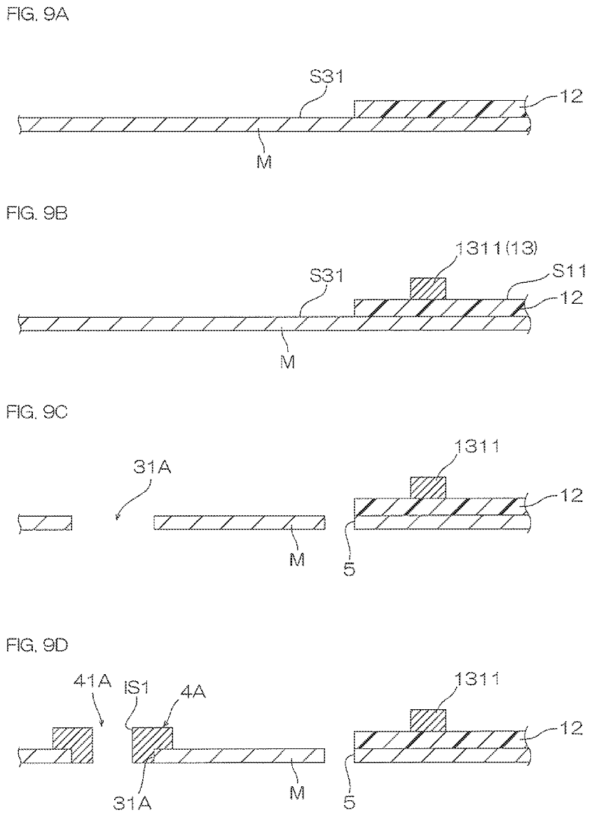

(5) As shown in FIGS. 9A and 9B, in the patterning step. the reinforcement portion 4 is not formed; as shown in FIG. 9C, when the metal foil M is etched, the through hole 31 is formed, and thereafter, as shown in FIG. 9D, the reinforcement portion 4 may be also formed on the edge of the through hole 31 and at the inside of the through hole 31 by the electrolytic plating.

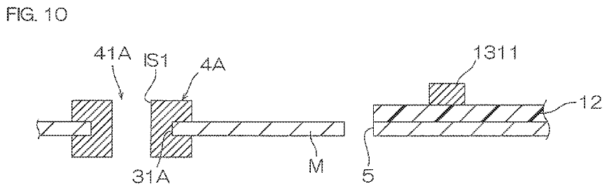

(6) As shown in FIG. 10. in the modified example of the above-described (5), the reinforcement portion 4 may be also formed on both surfaces of the metal foil M.

(7) As shown in FIG. 11, the reinforcement portion 30 may be also disposed on an other-surface S22 of the frame 3 in the thickness direction.

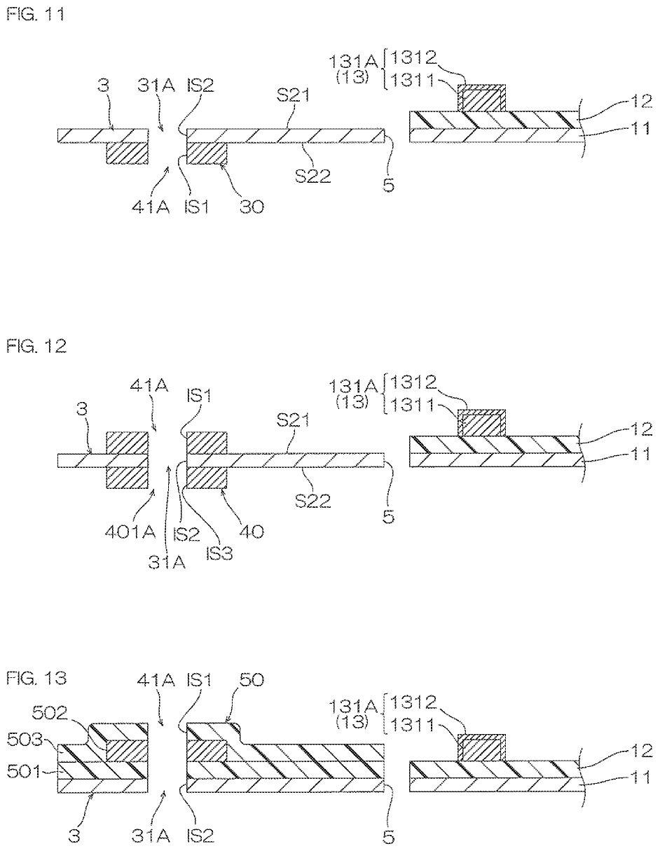

(8) As shown in FIG. 12, the assembly sheet 1 may also include the reinforcement portion 4 disposed on the one-surface S21 of the frame 3 in the thickness direction, and the reinforcement portion 40 disposed on the other-surface S22 of the frame 3 in the thickness direction. The reinforcement portion 40 may be also made of the same metal as the reinforcement portion 4. The reinforcement portion 40 has a through hole 401. The through hole 401 communicates with the through hole 31. An inner surface IS3 of the through hole 401 is preferably flush with the inner surface IS2 of the through hole 31.

According to such a configuration, it is possible to provide the reinforcement portion (the reinforcement portion 4 and the reinforcement portion 40) on both surfaces of the frame 3.

As a result, it is possible to further reinforce the frame 3.

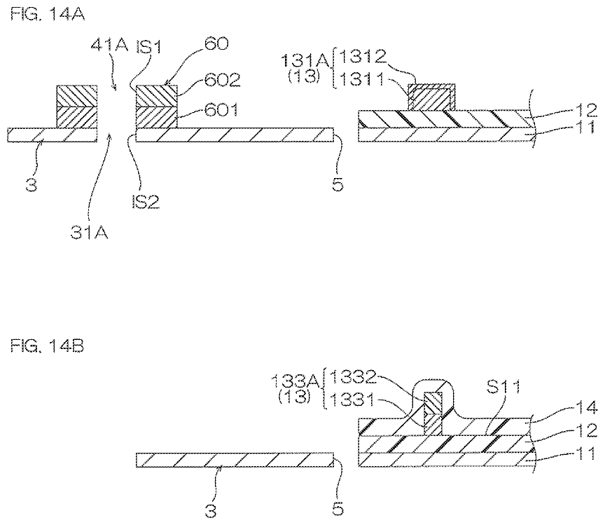

(9) As shown in FIG. 13, a reinforcement portion 50 may also have a first layer 501 made of the same resin as the base insulating layer 12, and a second layer 502 made of the same metal as the conductive layer 1311. The first layer 501 is disposed on the one-surface S21 of the frame 3. The second layer 502 is disposed on the first layer 501.

Further, the reinforcement portion 50 may also have a third layer 503 made of the same resin as the cover insulating layer 14. The third layer 503 is disposed on the second layer 502.

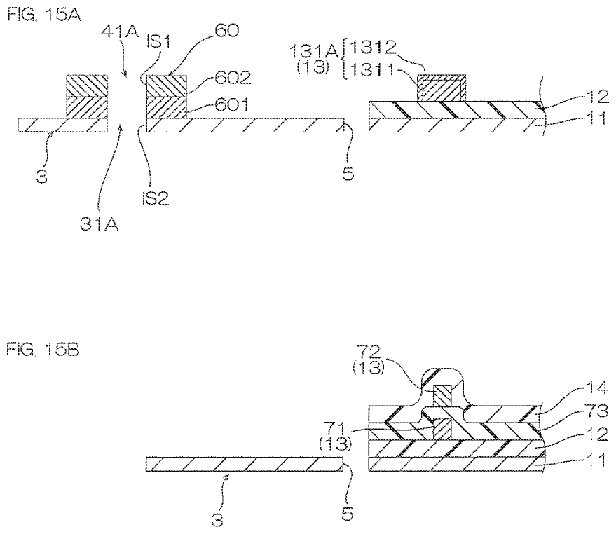

(10) As shown in FIG. 14A, a reinforcement portion 60 may also have a first layer 601 made of the metal and a second layer 602 made of the metal.

As shown in FIG. 14B, the wiring 133 may also have a first conductive layer 1331 and a second conductive layer 1332. The first conductive layer 1331 is disposed on the one-surface S11 of the base insulating layer 12 in the thickness direction. The first conductive layer 1331 may be also made of the same metal as the conductive layer 1311 of the terminal 131. The second conductive layer 1332 is disposed on the first conductive layer 1331 in the thickness direction. At least a portion of the second conductive layer 1332 is in contact with the first conductive layer 1331. In other words, the second conductive layer 1332 is electrically connected to the first conductive layer 1331.

In this case, the first layer 601 (ref: FIG. 14A) of the reinforcement portion 60 may be also made of the same metal as the first conductive layer 1331. The second layer 602 (ref: FIG. 14A) may be also made of the same metal as the second conductive layer 1332.

According to such a configuration, it is possible to form the reinforcement portion 60 by using a step of forming the first conductive layer 1331 and a step of forming the second conductive layer 1332.

Therefore, it is possible to improve a degree of freedom in design of the conductive pattern 13, and to form the reinforcement portion 60, while suppressing an increase in the number of steps.

(11) As shown in FIG. 15B, the conductive pattern 13 may also have a first wiring 71 and a second wiring 72. The assembly sheet 1 may also have an intermediate insulating layer 73.

The first wiring 71 is disposed on the base insulating layer 12. The first wiring 71 is formed by the electrolytic plating in the same manner as the above-described wiring 133.

The second wiring 72 is disposed away from the first wiring 71. In other words, the second wiring 72 is not electrically conducted to the first wiring 71. The second wiring 72 is disposed on the intermediate insulating layer 73. The second wiring 72 is formed by the electrolytic plating in the same manner as the above-described wiring 133.

The intermediate insulating layer 73 is disposed between the first wiring 71 and the second wiring 72. The intermediate insulating layer 73 insulates the first wiring 71 from the second wiring 72. The intermediate insulating layer 73 is formed on the first wiring 71 and the base insulating layer 12 in the same manner as the base insulating layer 12.

In this case, the first layer 601 (ref: FIG. 15A) of the reinforcement portion 60 may be also made of the same metal as the first wiring 71. The second layer 602 (ref: FIG. 15A) may be also made of the same metal as the second wiring 72.

According to such a configuration, it is possible to form the reinforcement portion 60 by using a step of forming the first wiring 71 and a step of forming the second wiring 72.

Therefore, it is possible to improve the degree of freedom in the design of the conductive pattern 13, and to form the reinforcement portion 60, while suppressing the increase in the number of steps.

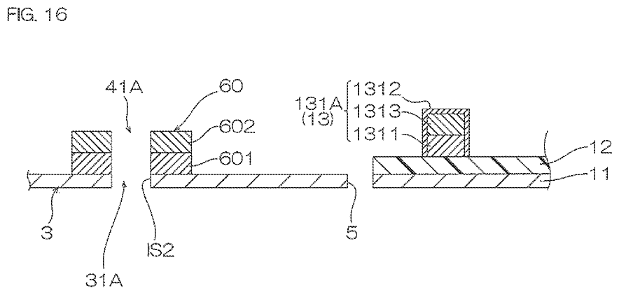

(12) As shown in FIG. 16. the terminal 131 or the terminal 132 may also further have a second conductive layer 1313 disposed on the conductive layer 1311.

In this case, the first layer 601 of the reinforcement portion 60 may be also made of the same metal as the conductive layer 1311. The second layer 602 may be also made of the same metal as the second conductive layer 1313.

(13) The above-described embodiment and each modified example can be used in combination.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The assembly sheet of the present invention and the method for producing an assembly sheet of the present invention are used in production of a wiring circuit board.

### DESCRIPTION OF REFERENCE NUMERALS

1 Assembly sheet
2 Wiring circuit board
3 Frame
31 Through hole
1 Reinforcement portion
11 Through hole
11 Support layer
S1 One surface of support layer
12 Base insulating layer
S11 One surface of base insulating layer
13 Conductive pattern
131 Terminal
132 Terminal
M Metal forl
R1 First roll
R2 Second roll

1. An assembly sheet comprising:
a wiring circuit board having a support layer, an insulating layer disposed on one surface of the support layer in a thickness direction, and a conductive pattern disposed on one surface of the insulating layer in the thickness direction;
a frame supporting the wiring circuit board and having a through hole; and
a reinforcement portion disposed on the edge of the through hole and reinforcing the edge of the through hole.

2. The assembly sheet according to claim 1, wherein
the frame is made of a metal foil having a thickness of 50 μm or less and
a thickness of the reinforcement portion is 6 μm or more.

3. The assembly sheet according to claim 2, wherein
when a thickness of the frame is 100%, the thickness of the reinforcement portion is 50% or more.

4. The assembly sheet according to claim 1, wherein
the reinforcement portion has a second through hole communicating with the through hole, and
an inner surface of the second through hole is flush with the inner surface of the through hole.

5. The assembly sheet according to claim 1, wherein
the through hole is capable of receiving an instrument for suspending the assembly sheet.

6. A method for producing an assembly sheet, the assembly sheet according to claim 1, comprising:
a patterning step of forming an insulating layer and a conductive pattern on one surface of a metal foil drawn from a first roll as a roll of the metal foil, forming a reinforcement portion on one surface of the metal foil, and forming a through hole in the metal foil to produce a second roll having the plurality of assembly sheets; and
a cutting step of cutting each of the plurality of assembly sheets from the second roll, wherein
the through hole receives an instrument for suspending the cut assembly sheet.

7. The method for producing an assembly sheet according to claim 6 further comprising:
a plating step of plating a terminal of the conductive pattern, wherein
the through hole receives the instrument in the plating step.
